(19) United States
(12) Patent Application Publication
(10) Pub. No.: US 2024/0237455 A1
(43) Pub. Date: Jul. 11, 2024

(54) DISPLAY DEVICE

(71) Applicant: LG Display Co., Ltd., Seoul (KR)

(72) Inventors: Sohee LEE, Paju-si (KR); Seongho OH, Paju-si (KR)

(73) Assignee: LG Display Co., Ltd., Seoul (KR)

(21) Appl. No.: 18/383,743

(22) Filed: Oct. 25, 2023

(30) Foreign Application Priority Data
Jan. 6, 2023 (KR) 10-2023-0002486

(51) Int. Cl. H10K 59/35; H10K 59/80

(52) U.S. Cl. CPC H10K 59/35; H10K 59/873; H10K 59/879; H10K 2102/311

(57) ABSTRACT

In a display device, a main area and a bend area adjacent to the main area are located in a display area. A first subpixel is located in the bend area. A planarization layer includes a first concave portion located in the first subpixel and a first slope portion located outside the first concave portion. The first slope portion is located so that light emitted by an emitting layer is reflected in a front viewing angle direction by a first electrode. In this manner, luminance in the side viewing angle direction of the bending area is improved.

### CROSS REFERENCE TO RELATED APPLICATION

This application claims priority to Korean Patent Application No. 10-2023-0002486, filed in the Republic of Korea on Jan. 6, 2023, the entire disclosure of which is hereby expressly incorporated by reference into the present application.

### BACKGROUND

### Field

Embodiments of the present disclosure relate to a display device including a bend area.

### Discussion of the Related Art

Display devices for displaying various types of information on a screen are considered a key technology in the information and communication technology era and serve to deliver various types of information to users.

Along with technological development, the degree of freedom in the design of display devices has improved. Some display devices can include a bend area in which a peripheral portion of a display area has a curvature.

When a display device includes a bend area in a peripheral portion of a display area, the display area can be maximized while a bezel area is minimized. However, it can be difficult for a user to view information displayed on the bend area. For example, even in the case that the bend area is viewed by a user in a side view angle direction, the display quality of the display device viewed in the side view angle direction can be significantly lower than that in a front view angle direction of the display device.

In addition, there can be a limitation in that the luminance of the display device viewed in the front view angle direction can be lower than that in the side view angle direction.

Due to the above-described limitations, it can be difficult for the display device having the bend area in the peripheral portion of the display area to realize excellent display quality in the bend area. As such, a bend area that provides an improved viewing quality is desired.

### BRIEF SUMMARY OF THE DISCLOSURE

When a display area includes a bend area in a peripheral portion thereof, a user can view the bend area in a side view angle direction due to the characteristics of the bend area. However, when the bend area is viewed in the side view angle direction, there can be an issue of low luminance. In this regard, the inventors of the present disclosure have made the present disclosure that can have superior luminance in the bend area and address the above-identified and other limitations associated with the related art.

Embodiments of the present disclosure can provide a display device including a normal area (or main area) located in a display area; a bend area located in the display area and outside the normal area; a first subpixel located in the bend area; and a planarization layer including a first concave portion located in the first subpixel and a first slope portion located outside the first concave portion. The first slope portion can be located so that light emitted by an emitting layer can be reflected in a front viewing angle direction by a first electrode. In this manner, luminance in the side viewing angle direction of the bending area can be improved.

Embodiments of the present disclosure can provide a display device having an improved efficiency due to a structure by which luminance in the side viewing angle direction of the bending area can be improved.

Embodiments of the present disclosure can provide a display device including a normal area, a bend area, a first subpixel, a planarization layer, a first electrode, and an emitting layer.

The normal area can be located in the display area. The bend area can be located in the display area and outside the normal area. The first subpixel can be located in the bend area.

The planarization layer can include a first concave portion and a first slope portion. The first concave portion can be located in the first subpixel. The first slope portion can be located outside the first concave portion.

The first electrode can be located in the first subpixel. The first electrode can be located on the first concave portion and the first slope portion.

The emitting layer can be located on the first electrode. The first slope portion can be located so that light emitted by the emitting layer can be reflected in a front viewing angle direction by the first electrode.

According to embodiments, the display device includes: a normal area located in a display area; a bend area located in the display area and outside the normal area; a first subpixel located in the bend area; and a planarization layer including a first concave portion located in the first subpixel and a first slope portion located outside the first concave portion. The first slope portion can be located so that light emitted by an emitting layer can be reflected in a front viewing angle direction by a first electrode. In this manner, luminance in the side viewing angle direction of the bending area can be improved.

### BRIEF DESCRIPTION OF THE DRAWINGS

The above and other objectives, features, and advantages of the present disclosure will be more clearly understood from the following detailed description, taken in conjunction with the accompanying drawings, in which:

FIG. 1 is a diagram illustrating a system configuration of an organic light-emitting display device according to embodiments of the present disclosure;

FIG. 2 is a diagram illustrating a schematic cross-sectional structure of the display device according to the embodiments of the present disclosure and a circuit structure of a subpixel of the display device;

FIG. 3 is a plan diagram illustrating a portion of the display device according to the embodiments of the present disclosure;

FIG. 4 is a cross-sectional diagram schematically illustrating an operation in a bend area of a display device according to a comparative example;

FIG. 5 is a cross-sectional diagram schematically illustrating an operation in the bend area of the display device according to the embodiments of the present disclosure;

FIG. 6 is a cross-sectional diagram illustrating a normal area and a bend area of the display device according to the embodiments of the present disclosure;

FIG. 7 is a diagram illustrating a slope angle in the display device according to the embodiments of the present disclosure;

FIG. 8 is a cross-sectional and plan diagram illustrating a first subpixel of the display device according to the embodiments of the present disclosure;

FIG. 9 is a cross-sectional and plan diagram illustrating a second subpixel of the display device according to the embodiments of the present disclosure;

FIG. 10 is a cross-sectional diagram illustrating the display device according to the embodiments of the present disclosure; and

FIG. 11 is a cross-sectional diagram schematically illustrating a normal area and a bend area in the display device according to the embodiments of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another.

Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

Hereinafter, a variety of embodiments of the present disclosure will be described in detail with reference to the accompanying drawings. All the components of each organic light-emitting display device according to all embodiments of the present disclosure are operatively coupled and configured.

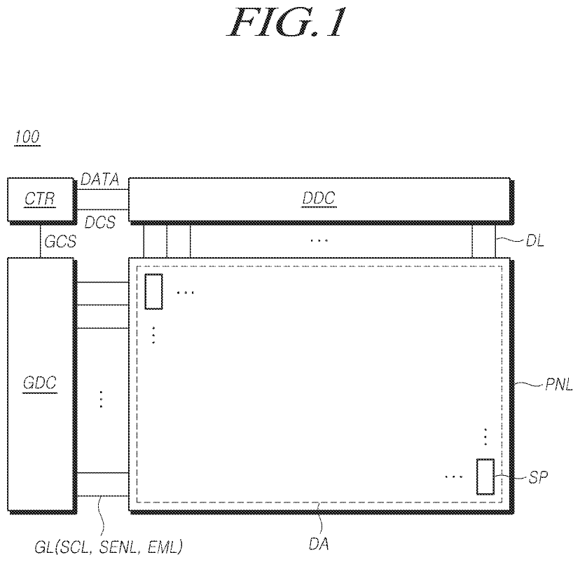

FIG. 1 is a diagram illustrating a system configuration of an organic light-emitting display device 100 according to embodiments of the present disclosure.

Referring to FIG. 1, an organic light-emitting display device 100 according to the embodiments can include a display panel PNL and at least one driver circuit. Here, a plurality of data lines DL and a plurality of gate lines GL are disposed in the display panel PNL, and a plurality of subpixels SP connected to the plurality of data lines DL and the plurality of gate lines GL are arranged in a display area DA (active area) of the display panel PNL. The driver circuit serves to drive the display panel PNL.

The driver circuit can include a data driver circuit DDC for driving the plurality of data lines DL, a gate driver circuit GDC for driving the plurality of gate lines GL, a controller CTR for controlling the data driver circuit DDC and the gate driver circuit GDC, and the like, in terms of the function.

In the display panel PNL, the plurality of data lines DL and the plurality of gate lines GL can be disposed to intersect. For example, the plurality of data lines DL can be disposed in rows or columns, and the plurality of gate lines GL can be disposed in columns or rows. Hereinafter, for the convenience of description, it will be assumed that the plurality of data lines DL are disposed in rows and the plurality of gate lines GL are disposed in columns.

The controller CTR controls the data driver circuit DDC and the gate driver circuit GDC by transmitting a variety of control signals DCS and GCS needed for the driving operation of the data driver circuit DDC and the gate driver circuit GDC.

The controller CTR starts scanning at timing defined for respective frames, converts image data input from an external source into a data signal format readable by the data driver circuit DDC, outputs the converted image data, and controls data driving at appropriate points in time in response to the scanning.

The controller CTR can be a timing controller used in general display technology or can be a control device including a timing controller and performing other control functions.

The controller CTR can be implemented as a component separate from the data driver circuit DDC or can be integrated with the data driver circuit DDC into an integrated circuit (IC).

The data driver circuit DDC drives the plurality of data lines DL by supplying image data, received from the controller CTR, to the plurality of data lines DL. Here, the data driver circuit DDC can also be referred to as a source driver circuit.

The data driver circuit DDC can include one or more source-driver integrated circuits (S-DICs). Each of the source-driver integrated circuits can include a shift register, a latch circuit, a digital-to-analog converter (DAC), an output buffer, and the like. In some cases, each of the source-driver integrated circuits can further include an analog-to-digital converter (ADC).

Each of the source-driver integrated circuits can be connected to a bonding pad of the display panel PNL using a tape-automated bonding (TAB) structure or a chip-on-glass (COG) structure, directly disposed on the display panel PNL, or in some cases, can be integrated into the display panel PNL. In addition, each of the source-driver integrated circuits can be implemented using a chip-on-film (COF) structure mounted on a source-circuit film connected to the display panel PNL.

The gate driver circuit GDC sequentially drives the plurality of gate lines GL by sequentially supplying a scan signal to the plurality of gate lines GL. Herein, the gate driver circuit GDC can also be referred to as a scan driver.

The gate driver circuit GDC can be connected to bonding pads of the display panel PNL using a TAB structure or a COG structure, can be implemented using a gate-in-panel (GIP) structure directly mounted on the display panel PNL, or in some cases, can be integrated into the display panel PNL. In addition, the gate driver circuit GDC can be comprised of a plurality of gate driver integrated circuits (G-DICs) implemented using a COF structure mounted on a gate-circuit film connected to the display panel PNL.

The gate driver circuit GDC sequentially supplies a scan signal having an on or off voltage to the plurality of gate lines GL, under the control of the display controller CTR.

When a specific gate line is opened by the gate driver circuit GDC, the data driver circuit DDC converts the image data DATA, received from the display controller CTR, into an analog data voltage and supplies the converted data voltage to the plurality of data lines DL.

The data driver circuit DDC can be disposed on one side of (e.g., on the upper or lower portion of or above or below) the display panel PNL or, in some cases, on both sides of (e.g., on the upper and lower portions of or above and below) the display panel PNL, depending on the driving method, the design of the display panel, or the like.

The gate driver circuit GDC can be disposed on one side (e.g., on the right or left portion or to the right or left; or on the top or bottom portion) of the display panel PNL or, in some cases, on both sides (e.g., on the right and left portions or to the right and left; or on the top and bottom portions) of the display panel PNL, depending on the driving method, the design of the display panel, or the like.

The plurality of gate lines GL disposed on the display panel PNL can include a plurality of scan lines SCL, a plurality of sensing lines SENL, and a plurality of emission control lines EML. The plurality of scan lines SCL, the plurality of sensing lines SENL, and the plurality of emission control lines EML are conductive lines transferring different types of gate signals (e.g., scan signals, sensing signals, and emission control signals) to gate nodes of different types of transistors (e.g., scan transistors, sensing transistors, and emission control transistors).

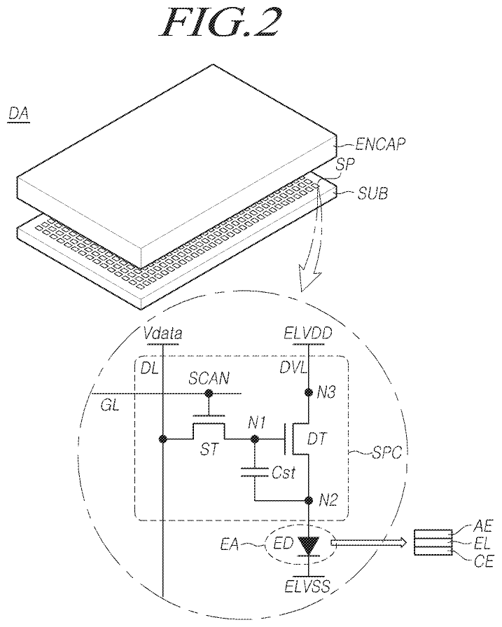

FIG. 2 is a diagram illustrating a schematic cross-sectional structure of a display device according to the embodiments of the present disclosure and a circuit structure of a subpixel of the display device. The display area shown in FIG. 2 is an example of the display DA of the display device.

Referring to FIG. 2, the plurality of subpixels SP can be disposed in the display area DA of the display device 100.

Each of the plurality of subpixels SP can include a light-emitting element ED and a subpixel circuit part SPC configured to drive the corresponding light-emitting element ED.

The subpixel circuit part SPC can include a driving transistor DT for driving the light-emitting element ED, a scan transistor ST for transferring a data voltage Vdata to a first node N1 of the driving transistor DT, a storage capacitor Cst for maintaining a predetermined voltage for a one-frame period, and the like.

The driving transistor DT can include the first node N1 to which a data voltage can be applied, a second node N2 electrically connected to the light-emitting element ED, and a third node N3 to which a drive voltage ELVDD is supplied from a drive voltage line DVL. In the driving transistor DT, the first node N1 can be a gate node, the second node N2 can be a source node or a drain node, and the third node N3 can be a drain node or a source node. Hereinafter, in the driving transistor DT, the first node N1 will be illustrated as a gate node, the second node N2 will be illustrated as a source node, and the third node N3 will be illustrated as a drain node, for the convenience of description.

The light-emitting element ED can include an anode AE, an emitting layer EL, and a cathode CE. The anode AE can be a pixel electrode disposed in each of the subpixels SP, and can be electrically connected to the second node N2 of the driving transistor DT of the corresponding subpixel SP. The cathode CE can be a common electrode disposed on two or more subpixels SP in common, and a base voltage ELVSS can be applied to the cathode CE.

For example, the anode AE can be a pixel electrode, and the cathode CE can be a common electrode. In contrast, the anode AE can be a common electrode, and the cathode CE can be a pixel electrode. Hereinafter, for the convenience of description, the anode AE will be assumed as a pixel electrode, and the cathode CE will be assumed as a common electrode.

The light-emitting element ED can have an emitting area EA. The emitting area EA of the light-emitting element ED can be defined as an area in which the anode AE, the emitting layer EL, and the cathode CE overlap.

For example, the light-emitting element ED can be an organic light-emitting diode (OLED), an inorganic light-emitting diode, a quantum dot light-emitting element, or the like. When the light-emitting element ED is an OLED, the emitting layer EL in the light-emitting element ED can include an organic emitting layer EL including an organic material.

The scan transistor ST is on-off controlled by a scan signal SCAN, i.e., a gate signal, applied through a gate line GL. The scan transistor ST can be electrically connected to the first node N1 of the driving transistor DT and a data line DL.

The storage capacitor Cst can be electrically connected to the first node N1 and the second node N2 of the driving transistor DT.

The subpixel circuit part SPC can have a 2T1C structure consists of two transistors DT and ST and a single capacitor Cst, as illustrated in FIG. 2. In some cases, the subpixel circuit part SPC can further include one or more transistors or one or more capacitors, so as to have other structures.

The storage capacitor Cst can be an external capacitor intentionally designed to be provided externally of the driving transistor DT, rather than a parasitic capacitor (e.g., Cgs or Cgd), i.e., an internal capacitor present between the first node N1 and the second node N2 of the driving transistor DT. Each of the driving transistor DT and the scan transistor ST can be an n-type transistor or a p-type transistor.

Since circuit elements (in particular, the light-emitting element ED implemented as the OLED including an organic material) in each of the subpixels is vulnerable to external moisture, oxygen, or the like, an encapsulation layer ENC for preventing external moisture or oxygen from infiltrating into the circuit elements (in particular, the light-emitting element ED) can be provided. The encapsulation layer ENC can have a shape covering the light-emitting elements ED.

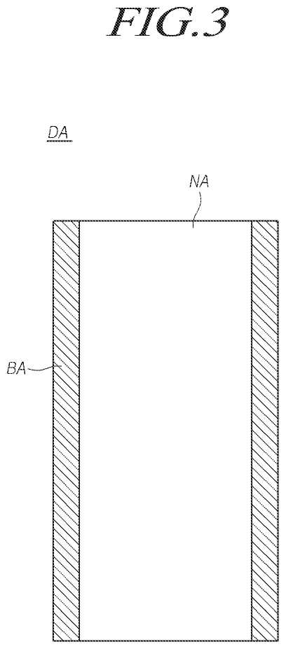

FIG. 3 is a plan diagram illustrating a portion of the display device according to the embodiments of the present disclosure. More specifically, FIG. 3 is a plan diagram of the display area DA of the display device according to the embodiments.

Referring to FIG. 3, the display area DA can include a normal area NA and a bend area BA. The normal area NA can be located in the display area DA. The bend area BA can be located in the display area DA.

The normal area NA can be a portion of the display area DA that is a flat portion with no curvature. The normal area NA can be referred to herein as a main area, a flat area, or a non-bend area.

The bend area BA can be located outside the normal area NA. In the example shown, the bend area BA can be disposed on opposite sides of the display area DA with the normal area NA disposed therebetween. The bend area BA can be a portion of the display area DA with a curvature. The bend area BA can have a curvature, for example, in a direction away from a user, and can have a shape curved or curled in a backward direction. Due to this shape of the bend area BA, when the user views the display device, the bend area BA can be viewed in a side view angle direction. For instance, the bend area BA can be disposed at one or more peripheral areas outside the normal area NA.

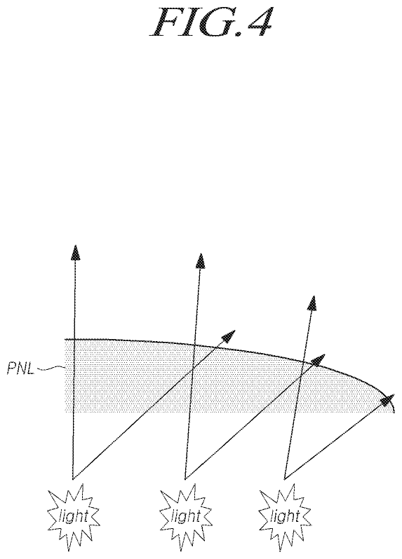

FIG. 4 is a cross-sectional diagram schematically illustrating an operation in a bend area of a display device according to a comparative example. Here, an exploded portion of the bend area is shown as an example only.

Referring to FIG. 4, a display panel can have a shape in which the bend area is curved or curled in a backward direction. Light generated by the bend area BA of the display panel travels toward a viewing surface. Here, it can be seen that the more peripheral the bend area is, the more light can travel in a side view angle direction. Thus, when the user views light generated from the bend area, display quality can be reduced.

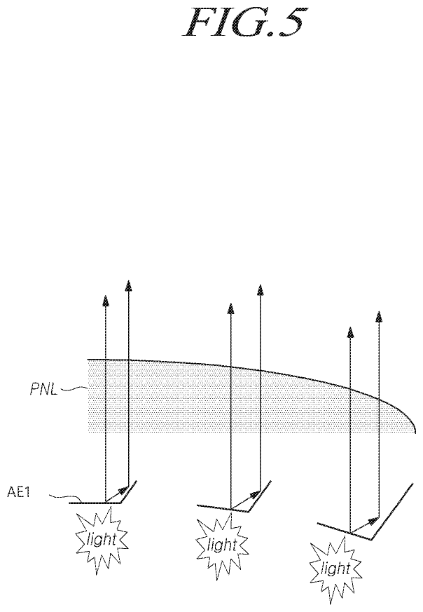

To address this issue, FIG. 5 shows a cross-sectional diagram schematically illustrating an operation in a bend area of a display device according to the embodiments of the present disclosure. The bend area of FIG. 5 can be the bend area BA of FIGS. 1-3 and 6-11.

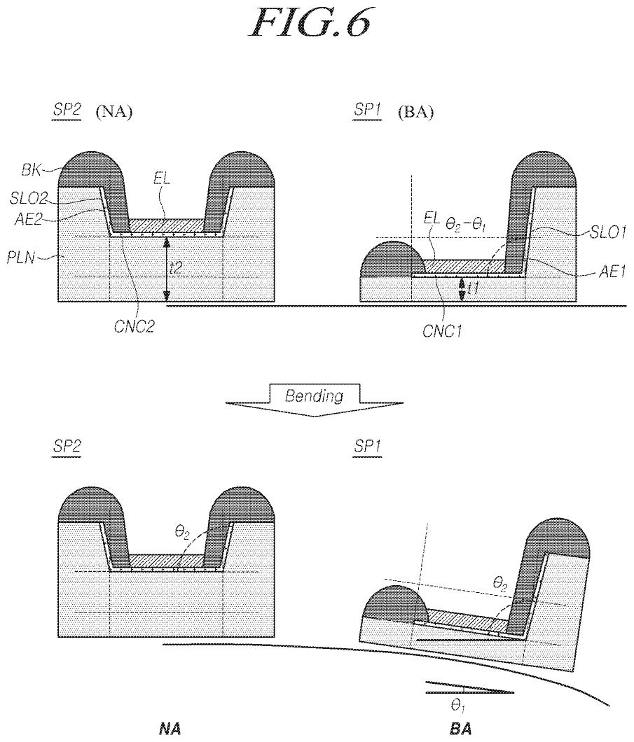

Referring to FIG. 5, the display panel PNL includes a first electrode AE of the present disclosure, and can have a shape in which the bend area is curved or curled in a backward direction of a viewing surface. The display device can be configured such that, even in the case that light generated from the bend area travels in a side view angle direction, the first electrode AE1 can reflect the light to travel in a front view angle direction or more toward the front view angle direction. For instance, heights of the first electrodes (AE1) in the bend area BA increase as the subpixels in the bend area get closer to the peripheral end of the bend area, as shown in FIG. 5. Thus, the display device according to embodiments of the present disclosure can have superior display quality even in the bend area. The specific structure including the first electrode AE1 according to one or more examples of the present disclosure will now be described referring to FIG. 6

FIG. 6 is a cross-sectional diagram illustrating a normal area and a bend area of a display device according to embodiments of the present disclosure. More specifically, FIG. 6 illustrates the cross-section of the display device according to embodiments including the cross-section before bending (top portion) and after bending (bottom portion) for a better understanding.

Referring to FIG. 6, the display device can include a normal area NA including a second subpixel SP2, a bend area BA including a first subpixel SP1, a planarization layer PLN in the first and second subpixels SP1 and SP2, a first electrode AE1, and an emitting layer EL in the first and second subpixels SP1 and SP2. The planarization layer PLN in the first and second subpixels SP1 and SP2 can have different thicknesses (e.g., t1 and t2) and can have first and second concave portions CNC1 and CNC2, respectively. The first electrode AE1 and a second electrode AE2 are disposed in the first and second concave portions CNC1 and CNC2, respectively. The emitting layer EL is disposed on the first and second electrodes AE1 and AE2. A bank BK is also disposed on the emitting layer El and the first and second electrodes AE1 and AE2.

In this example, the normal area NA and the bend area BA can be located in the display area DA as described above with reference to FIGS. 1 and 3. In addition, the bend area BA can be located outside the normal area NA.

The first subpixel SP1 can be located in the bend area BA. In description of embodiments illustrated in FIG. 6, the first subpixel SP1 can be a subpixel among subpixels located in the bend area BA.

The first subpixel SP1 can be located at a point at which a bent viewing surface is at a first angle θ₁ from a viewing surface of the normal area NA. The first angle θ₁ is shown on the right bottom portion of the drawing. That is, the first subpixel SP1 can be located at a point at which the angle between the first concave portion CNC1 and the second concave portion CNC2 is the first angle θ₁.

The planarization layer PLN can include the first concave portion CNC1 and a first slope (first slope portion) SLO1. The first concave portion CNC1 can be located in the first subpixel SP1. The first slope portion SLO1 can be located outside the first concave portion CNC1 and extends directly from the first concave portion CNC1. For example, the planarization layer PLN can include the first concave portion CNC1 and the first slope portion SLO1 in the first subpixel SP1 located in the bend area BA.

The first electrode AE1 can be located in the first subpixel SP1. In this example, the first electrode AE1 can be a pixel electrode corresponding to the first subpixel SP1, i.e., an electrode for driving the emitting layer EL located in the first subpixel SP1. In this example, the first electrode AE1 can be an anode for driving the emitting layer EL located in the first subpixel SP1. The first electrode AE1 can be located on the first concave portion CNC1 and the first slope portion SLO1. In this example, the first electrode AE1 can be a reflective electrode.

The emitting layer EL can be located on the first electrode AE1. For example, the emitting layer EL for generating light in the first subpixel SP1 can be located on the first electrode AE1. As the emitting layer EL is located on the first electrode AE1, the emitting layer EL can constitute a light-emitting element together with the first electrode AE1. Unlike that illustrated in FIG. 6, the emitting layer EL can be located on the front surface of the display area DA of the display device in common.

As the first electrode AE1 is located on the first concave portion CNC1 and extends onto the first slope portion SLO1 and as the emitting layer EL is located on the first electrode AE1, a ray of light traveling toward the peripheral portion of the display area DA, among rays of light generated by the emitting layer EL, is reflected by the first electrode AE1 located on the first slope portion SLO1. Thus, as illustrated in FIG. 5, due to the bent nature of the first electrode AE1, light generated by the subpixel located in the bend area BA can also travel in the forward direction (e.g., toward the front direction) of the panel PNL.

The first slope portion SLO1 can be located such that light emitted from the emitting layer EL can be reflected in the front view angle direction by the first electrode AE1. As illustrated in the comparative example of FIG. 4, light emitted from the bend area there is emitted in a side direction of the display panel. However, in the example of the present disclosure as illustrated in FIG. 5, when the first electrode AE1 is a reflective electrode and the first electrode AE1 in the bend area is located such that light emitted from the emitting layer EL can be reflected in the front view angle direction of the display panel PNL, then light emitted from the bend area BA as shown in FIG. 6 can also be emitted in the forward (front) direction of the display panel PNL.

In the present disclosure, when the first slope portion SLO1 is located such that light emitted from the emitting layer EL can be reflected in the front view angle direction by the first electrode AE1, the front view angle direction can indicate a direction perpendicular to the viewing surface of the display device. In addition, the location of the first slope portion SLO1 allowing light emitted from the emitting layer EL to be reflected in the front view angle direction by the first electrode AE1 can indicate that the first slope portion SLO1 is located to allow light emitted from the emitting layer EL to be reflected in the front view angle direction, in consideration of the curvature of the bend area, the position of the display area, and the position of the bend area.

For example, as illustrated in FIG. 3, the bend area BA can be located outside the normal area NA. As illustrated in FIGS. 5 and 6, the curvature of the bend area BA can be set such that the viewing surface of the bend area BA is curved toward the opposite surface of the display area DA. In this example, the first slope portion SLO1 can be located more peripheral than the first concave portion CNC1 in the display area DA. For example, the first slope portion SLO1 in the bend area BA can be located on a path on which a ray of light, among rays of light generated by the emitting layer EL located in the first concave portion CNC1, travels toward the peripheral portion instead of the central portion of the display area DA. Since the first slope portion SLO1 is located in this manner, the bend area BA of the display device can have more superior display quality in the side view angle direction.

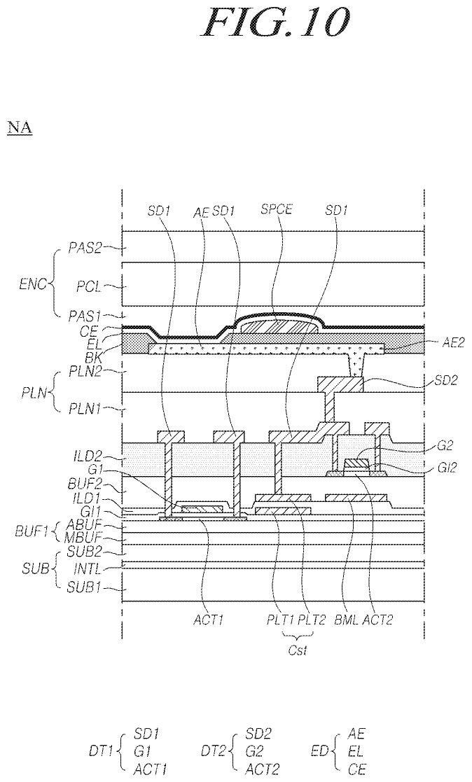

Referring to FIG. 6, the display device can further include the second subpixel SP2 located in the normal area NA. In embodiments illustrated in FIG. 6, the planarization layer PLN in the second subpixel SP2 includes the second concave portion CNC2 and a second slope (second slope portion) SLO2 extending directly from the second concave portion CNC2. In another example, as illustrated in FIG. 10, the planarization layer PLN in the second subpixel SP2 located in the normal area NA may not include a concave portion or a slope/slope portion.

The second thickness t2 of a portion of the planarization layer PLN corresponding to the emitting layer EL of the second subpixel SP2 can be larger than the first thickness t1 of a portion of the planarization layer PLN corresponding to the emitting layer EL of the first subpixel SP1. In this example, the portion corresponding to the emitting layer EL of the second subpixel SP2 can mean a portion in which an emitting element of the second subpixel SP2 is located, and the portion corresponding to the emitting layer EL of the first subpixel SP1 can mean a portion in which an emitting element of the first subpixel SP1 is located. In this example, in the first subpixel SP1 located in the bend area BA, the first slope portion SLO1 (having a specific slope) can extend advantageously higher than the emitting layer EL in order to reflect light generated by the emitting layer EL in the front view angle direction of the display device. Thus, the portion of the planarization layer PLN corresponding to the emitting layer EL of the first subpixel SP1, i.e., the portion corresponding to the light-emitting element, can have a low thickness (e.g., first thickness t1) due to processing such as etching. The first thickness t1 can be the thickness of the planarization layer PLN in the first concave portion CNC1.

When the planarization layer PLN has the second concave portion CNC2 and the second slope portion SLO2 extending therefrom in the second subpixel SP2 located in the normal area NA, the second thickness t2 can be the thickness of the planarization layer PLN in the second concave portion CNC2. In this example, the first thickness t1 being less (or thinner) than the second thickness t2 can mean that the height of the first slope portion SLO1 is higher (or larger) than the height of the second slope portion SLO2. The height of the first slope portion SLO1 can mean the vertical height of the first slope portion SLO1 with respect to the first concave portion CNC1, and the height of the second slope portion SLO2 can mean the vertical height of the second slope portion SLO2 with respect to the second concave portion CNC2.

The display device can include the second electrode AE2 in the normal area NA. The second electrode AE2 can be located in the second subpixel SP2 and on the planarization layer PLN. For example, the second electrode AE2 can be a pixel electrode corresponding to the second subpixel SP2, i.e., an electrode for driving the emitting layer EL of the second subpixel SP2. In this example, the second electrode AE2 can be an anode for driving the emitting layer EL located in the second subpixel SP2. The second electrode AE2 can be located on the second concave portion CNC2 and the second slope portion SLO2. In this example, the second electrode AE2 can be a reflective electrode.

The planarization layer PLN can include the second concave portion CNC2 located in the second subpixel SP2 and the second slope portion SLO2 extending directly from the second concave portion CNC2 and located outside the second concave portion CNC2. In this example, the second electrode AE2 can be located on the second concave portion CNC2 and the second slope portion SLO2. The emitting layer EL can be located on the second electrode AE2. Due to this structure of the second subpixel SP2, the second electrode AE2 located on the second slope portion SLO2 can reflect light generated by the emitting layer EL, thereby allowing the display device to have higher light efficiency and more superior viewing angle characteristics.

The second slope portion SLO2 can be at a second angle θ₂ from the second concave portion CNC2. The first concave portion CNC1 can be at the first angle θ₁ from the second concave portion CNC2. In this example, the angle between (formed by) the first slope portion SLO1 and the first concave portion CNC1 can be the same as an angle obtained by subtracting the first angle θ₁ from the second angle θ₂. That is, the angle between the first slope portion SLO1 and the first concave portion CNC1 can be the same as an angle obtained by subtracting the angle θ₁ at which the first slope portion SLO1 is inclined due to the curvature of the bend area BA from the angle between the second slope portion SLO2 and the second concave portion CNC2.

When the first slope portion SLO1 and the second slope portion SLO2 have this angle relationship, side viewing angle characteristics of the first subpixel SP1 located in the bend area BA can be optimized in accordance with a user located and viewing in the front viewing angle direction of the normal area NA.

The emitting layer EL can be located on the second electrode AE2. The emitting layer EL located on the second electrode AE2 can constitute a light-emitting element located in the second subpixel SP2.

The structure in which the first electrode AE1 located on the first slope portion SLO1 surrounds the emitting layer EL and the structure in which the second electrode AE2 located on the second slope portion SLO2 surrounds the emitting layer EL, as described above with reference to FIG. 6, can be referred to as a side mirror structure herein. In particular, the structure in which the first electrode AE1 located on the first slope portion SLO1 surrounds the emitting layer EL can be referred to as a half side mirror structure, and the structure in which the second electrode AE2 located on the second slope portion SLO2 surrounds the emitting layer EL can be referred to as a full side mirror structure.

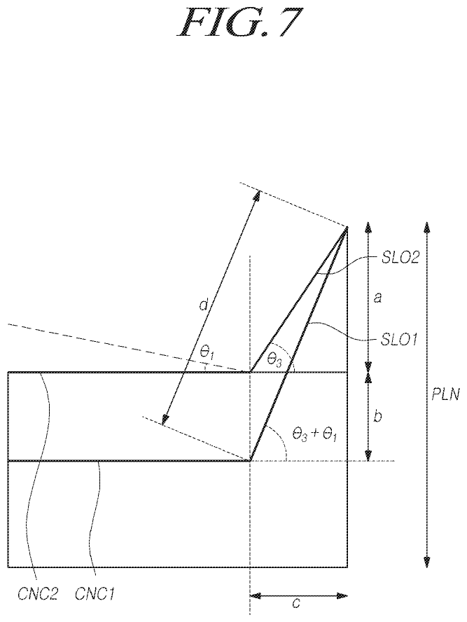

FIG. 7 is a diagram illustrating a slope angle in the display device according to the embodiments of the present disclosure. More specifically, FIG. 7 illustrates both the first and second slope portions SLO1 and SLO2 interposed on each other to show a relationship between the first slope portion SLO1 and the second slope portion SLO2 of the display device illustrated in FIG. 6.

Referring to FIG. 7, the height of the first slope portion SLO1 in the bend area BA can be “a+b,” and the height of the second slope portion SLO2 in the normal area NA can be “a.” Since both the first slope portion SLO1 and the second slope portion SLO2 are formed by etching the planarization layer PLN, the planarization layer PLN can have the same thickness at the highest points of the first slope portion SLO1 and the second slope portion SLO2.

The first slope portion SLO1 and the second slope portion SLO2 can have a same width c. When the first concave portion CNC1 can be inclined (or bent) in the bend area as indicated with a dotted line, the first concave portion CNC1 and the second concave portion CNC2 can have the first angle θ₁, which can be the angle due to the curvature of the bend area).

When the angle of the inclined surface of the second slope portion SLO2 is a third angle θ₃, the angle of the inclined surface of the first slope portion SLO1 can be θ₃+θ₁ obtained by adding the first angle θ₁ (i.e., the angle due to the curvature of the bend area) to the third angle θ₃. In this example, the length d of the second slope portion SLO2 can be expressed by the following equation:

[a/tan θ₃]*[tan(θ₃+θ₁)/sin(θ₃+θ₁)].

When the first slope portion SLO1 and the second slope portion SLO2 satisfy the above equation, the half side mirror structure of the first subpixel SP1 located in the bend area BA can extract light generated by the emitting layer EL toward or in the front viewing angle direction of the display device.

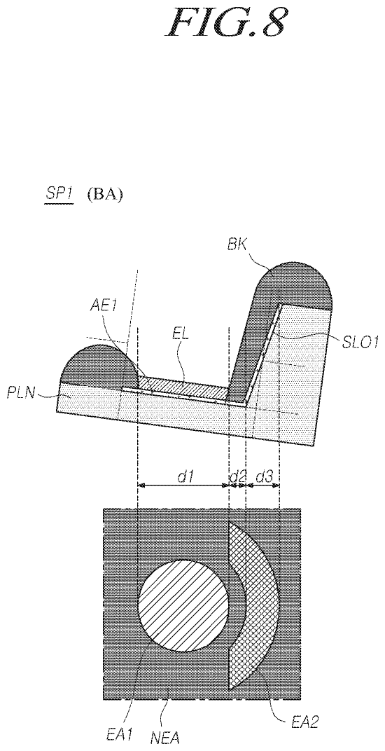

FIG. 8 shows cross-sectional (top) and plan (bottom) views illustrating an example of the first subpixel SP1 of the display device according to the embodiments of the present disclosure.

Referring to FIG. 8, the first subpixel SP1 in the bend area BA can include a first emitting area EA1, a second emitting area EA2, and a non-emitting area NEA. The second emitting area EA2 can be located outside the first emitting area EA1. In addition, the second emitting area EA2 can be located to surround a portion of the first emitting area EA1. The first emitting area EA1 can be a major emitting area of the first subpixel SP1, and the second emitting area EA2 can be a secondary emitting area (or an auxiliary emitting area) of the first subpixel SP1.

Referring to FIGS. 6 and 8, the first emitting area EA1 can be located to correspond to the first concave portion CNC1. The second emitting area EA2 can be located to correspond to the first slope portion SLO1. The first emitting area EA1 can be an area from which light generated by the emitting layer EL located in the first concave portion CNC1 is emitted. The second emitting area EA2 can be an area from which light reflected from the first electrode AE1 located on the first slope portion SLO1 is emitted.

The second emitting area EA2 can be located more peripheral than the first emitting area EA1 in the display area DA. For example, the first emitting area EA1 can be located closer to the central portion of the display area DA, and the second emitting area EA2 can be located closer to the peripheral portion of the display area DA. This is because the first slope portion SLO1 is located to reflect light emitted by the emitting layer EL in the front viewing angle direction of the display device and the second emitting area EA2 is located to correspond to the first slope portion SLO1.

Since the first subpixel SP1 includes the second emitting area EA2 surrounding a portion of the first emitting area EA1, the first subpixel SP1 located in the bend area BA can emit light in the front viewing angle direction of the display device.

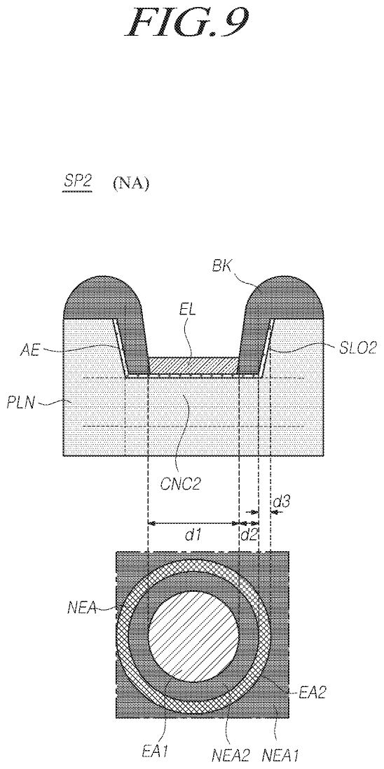

FIG. 9 shows cross-sectional (top) and plan (bottom) views illustrating an example of the second subpixel SP2 of the display device according to embodiments of the present disclosure.

Referring to FIG. 9, the second subpixel SP2 in the normal area (NA) can include a first emitting area EA1, a second emitting area EA2, a first non-emitting area NEA1, and a second non-emitting area NEA2.

The first emitting area EA1 can be a major emitting area of the second subpixel SP2. Referring to FIGS. 6 and 9, the first emitting area EA1 can be located to correspond to the second concave portion CNC2.

The second emitting area EA2 can be a secondary emitting area of the second subpixel SP2. The second emitting area EA2 can be located outside the first emitting area EA1. The second emitting area EA2 can be located to be spaced apart from the first emitting area EA1.

Referring to FIGS. 6 and 9, the second emitting area EA2 can be located to correspond to the second slope portion SLO2. Light emitted from the second emitting area EA2 can be light generated by the emitting layer EL and reflected from the second electrode AE2 located on the second slope portion SLO2.

The second non-emitting area NEA2 can be located between the first emitting area EA1 and the second emitting area EA2. The first non-emitting area NEA1 can be located outside the second emitting area EA2.

Referring to FIGS. 8 and 9, the second emitting area EA2, i.e., the secondary emitting area, has different shapes in the first subpixel SP1 and in the second subpixel SP2. In FIG. 8, in the first subpixel SP1, the second emitting area EA2 can be located to surround only a portion of the first emitting area EA1. In FIG. 9, in the second subpixel SP2, the second emitting area EA2 can be located to surround the entirety of the first emitting area EA1.

The width of the second emitting area EA2 in the first subpixel SP1 can be different from the width of the second emitting area EA2 in the second subpixel SP2. For example, when the width of the second emitting area EA2 in the first subpixel SP1 is d3 and the width of the second emitting area EA2 in the second subpixel SP2 is d3, then d3 in the first subpixel SP1 can be wider than d3 in the second subpixel SP2. This can be because the first subpixel SP1 is located in the bend area BA and the second subpixel SP2 is located in the normal area NA.

Alternatively, when the widths of the second emitting areas in two subpixels located in the bend area BA and having the half side mirror structure are compared, the width of the second emitting area of the subpixel located in the area having a greater curvature can be greater.

The distance between the first emitting area EA1 and the second emitting area EA2 can vary in the first subpixel SP1 and the second subpixel SP2. For example, when the distance between the first emitting area EA1 and the second emitting area EA2 in the first subpixel SP1 is d2 and the distance between the first emitting area EA1 and the second emitting area EA2 in the second subpixel SP2 is d2, then d2 in the second subpixel SP2 can be wider than d2 in the first subpixel SP1. This can be because the first subpixel SP1 is located in the bend area BA and the second subpixel SP2 is located in the normal area NA.

In addition, when the distances between the first emitting area and the second emitting area in two subpixels located in the bend area BA and having the half side mirror structure are compared, the distance between the first emitting area and the second emitting area can be shorter in the subpixel located in the area having a greater curvature.

FIG. 10 is a cross-sectional diagram illustrating the display device according to embodiments of the present disclosure. More specifically, FIG. 10 is a cross-sectional diagram of a normal area of the display area in the display device according to embodiments, and shows an example of the normal area of the present disclosure.

Referring to FIG. 10, the display device can include a transistor forming part, a light-emitting element forming part, and an encapsulation part.

The transistor forming part can include: a substrate SUB; a first buffer layer BUF1 on the substrate SUB; and a variety of transistors DT1 and DT2, a storage capacitor Cst, and a variety of electrodes or signal lines provided on the first buffer layer BUF1.

The substrate SUB can include a first substrate SUB1, a second substrate SUB2, and an interlayer INTL between the first substrate SUB1 and the second substrate SUB2. For example, the interlayer INTL can be an inorganic layer capable of blocking the infiltration of moisture.

The first buffer layer BUF1 can have a single layer structure or a multilayer structure. When the first buffer layer BUF1 has a multilayer structure, the first buffer layer BUF1 can include a multi-buffer layer MBUF and an active buffer layer ABUF.

The variety of transistors DT1 and DT2, the storage capacitor Cst, and the variety of electrodes or signal lines can be formed on the first buffer layer BUF1.

The first driving transistor DT1 can include a first active layer ACT1, a first gate electrode G1, and a first source-drain electrode SD1. The second driving transistor DT2 can include a second active layer ACT2, a second gate electrode G2, and a second source-drain electrode SD2.

The second active layer ACT2 of the second driving transistor DT2 can be positioned higher than the first active layer ACT1 of the first driving transistor DT1.

The storage capacitor Cst can include a first capacitor electrode PLT1 and a second capacitor electrode PLT2.

A bottom metal BML can be disposed below the second active layer ACT2 of the second driving transistor DT2. The bottom metal BML can overlap the entirety or a portion of the second active layer ACT2.

The planarization layer PLN can be located on the first driving transistor DT1 and the second driving transistor DT2. The planarization layer PLN can include a plurality of layers. For example, the planarization layer PLN can include a first planarization layer PLN1 and a second planarization layer PLN2 located on the first planarization layer PLN1.

The example illustrated in FIG. 10 does not include the concave portion or the slope portion (e.g., CNC2, SLO2) illustrated in FIG. 6. For example, the example illustrated in FIG. 10 is the cross-section of the subpixel not including the full size mirror structure or the half size mirror structure. In the display device according to embodiments, the subpixel located in the normal area rather than in the bend area may not include the side mirror structure.

The light-emitting element forming part can be located on the planarization layer PLN. The light-emitting element forming part can include a light-emitting element (or light-emitting diode) ED located on the planarization layer PLN.

The second electrode AE2 can be located on the planarization layer PLN. The second electrode AE2 can be an anode of the light-emitting element ED. A bank BK can be located on the second electrode AE2. The bank BK can have a hole, which can overlap a portion of the second electrode AE2.

The emitting layer EL can be located on the bank BK. In the example illustrated in FIG. 10, the emitting layer EL can be deposited to the entire surface of the display area in common. The emitting layer EL can be in contact with a portion of the second electrode AE2 through the hole in the bank BK.

At least one space SPCE can be located between the emitting layer EL and the bank BK. A cathode CE can be located on the emitting layer EL.

The encapsulation part can be located on the cathode CE. The encapsulation part can include an encapsulation layer ENC formed on the cathode CE.

The encapsulation layer ENC can be a layer preventing moisture or oxygen from infiltrating into the light-emitting element ED located below the encapsulation layer ENC. The encapsulation layer ENC can have a single layer structure or a multilayer structure. The encapsulation layer ENC can include a first passivation layer PAS1, an organic encapsulation layer PCL, and a second passivation layer PAS2.

Although the cross-sectional structure of the subpixel with no side mirror structure is illustrated in FIG. 10, the cross-sectional structure of a subpixel having the side mirror structure can also be similar to the cross-sectional structure illustrated in FIG. 10. For example, when the subpixel of the display device according to embodiments has the full side mirror structure or the half side mirror structure, the cross-sectional structure of the subpixel can be similar to the cross-sectional structure illustrated in FIG. 10, except that the configuration from the planarization layer to the light-emitting element forming part includes the side mirror structure.

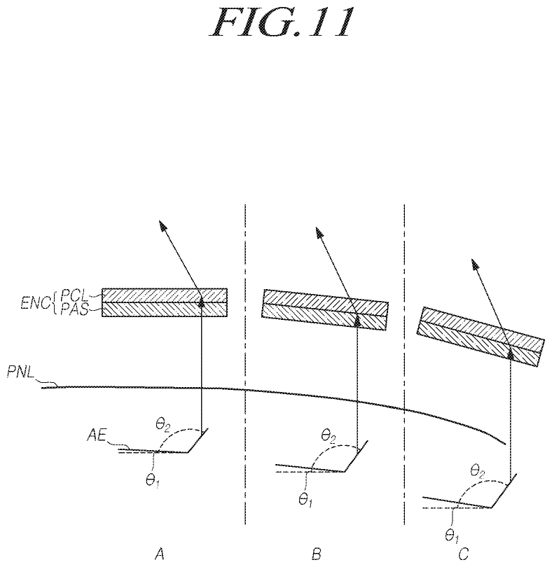

FIG. 11 is a cross-sectional diagram schematically illustrating a normal area and a bend area in the display device according to the embodiments of the present disclosure.

As described above with reference to FIG. 10, the display device according to embodiments can include an encapsulation layer ENC located on an emitting layer. The encapsulation layer ENC can include a high refractive index layer (first refractive index layer) PAS and a low refractive index layer (second refractive index layer) PCL located on the high refractive index layer PAS. For example, referring to FIGS. 10 and 11, the first passivation layer PAS1 described above with reference to FIG. 10 can be the high refractive index layer PAS illustrated in FIG. 11, and the organic encapsulation layer PCL described above with reference to FIG. 10 can be the low refractive index layer PCL illustrated in FIG. 11.

When the encapsulation layer ENC includes the low refractive index layer PCL located on the high refractive index layer PAS and the high refractive index layer PAS, light generated in the bend area can be extracted in the front viewing angle direction of the display device.

The refractive index of the area of the low refractive index layer PCL adjacent to the central portion of the display area can be higher than the refractive index of the area of the low refractive index layer PCL adjacent to the peripheral portion of the display area. For example, the more peripheral the display area is, the lower the refractive index of the low refractive index layer PCL can be. In this example, the difference in refractive index between the high refractive index layer PAS and the low refractive index layer PCL can increase in the direction of the peripheral portion of the display area in which the curvature of the bend area increases.

Referring to FIG. 11, the difference in refractive index between the high refractive index layer PAS and the low refractive index layer PCL in B area can be greater than the difference in refractive index between the high refractive index layer PAS and the low refractive index layer PCL in A area, whereas the difference in refractive index between the high refractive index layer PAS and the low refractive index layer PCL in C area can be greater than the difference in refractive index between the high refractive index layer PAS and the low refractive index layer PCL in B area.

In this example, as illustrated in FIG. 11, light generated in a subpixel located in the peripheral portion of the display panel PNL can be extracted in the front viewing angle direction of the display device. Here, areas A, B and C all can be part of the bend area B, where the configuration of the bend area BA shown in FIGS. 6-8 can be used. As such, even when the display device is bent, a user can enjoy a high quality of image displaying throughout the entire display panel including the bend area especially located at a peripheral area of the display panel.

The above-described embodiments of the present disclosure will be briefly reviewed as follows.

According to embodiments of the present disclosure, a display device 100 can include a normal area NA, a bend area BA, a first subpixel SP1, a planarization layer PLN, a first electrode AE1, and an emitting layer EL.

The normal area NA can be located in the display area DA. The bend area BA can be located in the display area DA and outside the normal area NA. The first subpixel SP1 can be located in the bend area BA.

The planarization layer PLN can include a first concave portion CNC1 and a first slope portion SLO1. The first concave portion CNC1 can be located in the first subpixel SP1. The first slope portion SLO1 can be located outside the first concave portion CNC1.

The first electrode AE1 can be located in the first subpixel SP1. The first electrode AE1 can be located on the first concave portion CNC1 and the first slope portion SLO1.

The emitting layer EL can be located on the first electrode AE1.

The first slope portion SLO1 can be located such that light emitted by the emitting layer EL can be reflected in a front viewing angle direction by the first electrode AE1.

The first slope portion SLO1 can be located more peripheral than the first concave portion CNC1 in the display area DA. The display device 100 can further include a second subpixel SP2 located in the normal area NA. The second thickness t2 of a portion of the planarization layer PLN corresponding to the emitting layer EL of the second subpixel SP2 is higher than the first thickness t1 of a portion of the planarization layer PLN corresponding to the emitting layer EL of the first subpixel SP2.

The display device 100 can further include a second electrode AE2. The second electrode AE2 can be located in the second subpixel SP2 while located on the planarization layer PLN.

The planarization layer PLN can include a second concave portion CNC2 located in the second subpixel SP2 and a second slope portion SLO2 located outside the second concave portion CNC2.

The second electrode AE2 can be located on the second concave portion CNC2 and the second slope portion SLO2. The emitting layer EL can be located on the second electrode AE2.

The angle between the first slope portion SLO1 and the first concave portion CNC1 is equal to an angle obtained by subtracting the first angle θ₁ between the first concave portion CNC1 and the second concave portion CNC2 from the second angle θ₂ between the second slope portion SLO2 and the second concave portion CNC2.

The first subpixel SP1 can include a first emitting area EA1, a second emitting area EA2 located outside the first emitting area EA1, and a non-emitting area NEA.

The first emitting area EA1 can be located to correspond to the first concave portion CNC1. The second emitting area EA2 can be located to correspond to the first slope portion SLO1.

The second subpixel SP2 can include a first emitting area EA1, a second emitting area EA2, a first non-emitting area NEA1, and a second non-emitting area NEA2. The second emitting area EA2 can be located outside and spaced apart from the first emitting area EA1. The second non-emitting area NEA2 can be located between the first emitting area EA1 and the second emitting area EA2. The first non-emitting area NEA1 can be located outside the second emitting area EA2.

The display device 100 can include a second subpixel SP2 located in the normal area NA and a second electrode AE2 located in the second subpixel SP2 while located on the planarization layer PLN. The planarization layer PLN can include a second concave portion CNC2 located in the second subpixel SP2 and a second slope portion SLO2 located outside the second concave portion CNC2. The second electrode AE2 can be located on the second concave portion CNC2 and the second slope portion SLO2. The emitting layer EL can be located on the second electrode AE2.

The second subpixel SP2 can include a first emitting area EA1, a second emitting area EA2 located outside and spaced apart from the first emitting area EA1, a first non-emitting area NEA1 located outside the second emitting area EA2, and a second non-emitting area NEA2 located between the first emitting area EA1 and the second emitting area EA2.

The width of the second emitting area EA2 of the first subpixel SP1 can be wider than the width of the second emitting area EA2 of the second subpixel SP2.

The display device 100 can further include an encapsulation layer ENC located on the emitting layer EL. The encapsulation layer ENC can include a high refractive index layer PAS and a low refractive index layer PCL located on the high refractive index layer PAS.

The refractive index of an area of the low refractive index layer PCL adjacent to a central portion of the display area DA can be higher than the refractive index of an area of the low refractive index layer PCL adjacent to a peripheral portion of the display area DA.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a main area located in a display area;
a bend area located in the display area and outside the main area;
a first subpixel located in the bend area;
a planarization layer including a first concave portion located in the first subpixel and a first slope portion extending from the first concave portion;
a first electrode located on the first concave portion and the first slope portion of the first subpixel; and
an emitting layer located on the first electrode,
wherein the first slope portion is located so that light emitted by the emitting layer is reflected towards a front viewing angle direction by the first electrode.

2. The display device according to claim 1, wherein the first slope portion is located more peripheral than the first concave portion in the display area.

3. The display device according to claim 1, further comprising a second subpixel located in the main area,
wherein a second thickness of a portion of the planarization layer corresponding to an emitting layer of the second subpixel in the main area is larger than a first thickness of a portion of the planarization layer corresponding to the emitting layer of the first subpixel in the bend area.

4. The display device according to claim 3, further comprising a second electrode located on the planarization layer in the second subpixel,
wherein the planarization layer further comprises a second concave portion located in the second subpixel and a second slope portion extending from the second concave portion,
the second electrode is located on the second concave portion and the second slope portion, and
the emitting layer is located on the second electrode.

5. The display device according to claim 4, wherein an angle between the first slope portion and the first concave portion in the bend area is equal to an angle obtained by subtracting a first angle between the first concave portion and the second concave portion from a second angle between the second slope portion and the second concave portion.

6. The display device according to claim 1, wherein the first subpixel comprises a first emitting area, a second emitting area located outside the first emitting area, and a non-emitting area.

7. The display device according to claim 6, wherein the first emitting area is located to correspond to the first concave portion, and
the second emitting area is located to correspond to the first slope portion.

8. The display device according to claim 4, wherein the second subpixel comprises a first emitting area, a second emitting area located outside and spaced apart from the first emitting area, a first non-emitting area located outside the second emitting area, and a second non-emitting area located between the first emitting area and the second emitting area.

9. The display device according to claim 6, further comprising:
a second subpixel located in the main area; and
a second electrode located on the planarization layer in the second subpixel,
wherein the planarization layer comprises a second concave portion located in the second subpixel and a second slope portion extending from the second concave portion,
the second electrode is located on the second concave portion and the second slope portion,
the emitting layer is located on the second electrode,
the second subpixel comprises a first emitting area, a second emitting area located outside and spaced apart from the first emitting area, a first non-emitting area located outside the second emitting area, and a second non-emitting area located between the first emitting area and the second emitting area, and
a width of the second emitting area of the first subpixel is wider than a width of the second emitting area of the second subpixel.

10. The display device according to claim 1, further comprising an encapsulation layer located on the emitting layer,
wherein the encapsulation layer comprises a first refractive index layer and a second refractive index layer located on the first refractive index layer, and a refractive index of the first refractive index layer is higher than a refractive index of the second refractive index layer.

11. The display device according to claim 10, wherein the refractive index of an area of the second refractive index layer adjacent to a central portion of the display area is higher than the refractive index of an area of the second refractive index layer adjacent to a peripheral portion of the display area.

12. The display device according to claim 1, further comprising a second subpixel located in the main area,
wherein a height of a portion of the planarization layer in the first subpixel with respect to the emitting layer of the first subpixel is larger than a height of a portion of the planarization layer in the second subpixel with respect to an emitting layer of the second subpixel.

13. The display device according to claim 1, further comprising:
a second subpixel located in the main area; and
a second electrode located on the planarization layer in the second subpixel,
wherein the first electrode surrounds a part of the emitting layer of the first subpixel to form a half side mirror structure, and the second electrode surrounds entirely an emitting layer of the second subpixel to form a full side mirror structure.

14. A display device comprising:
a display panel including a display area and a non-display area adjacent to the display area,
wherein the display area includes a main area and a bend area adjacent to the main area, and a plurality of subpixels disposed in the main area and the bend area,
the plurality of subpixels include a first subpixel disposed in the bend area and a second subpixel disposed in the main area,
a planarization layer is disposed in the first and second subpixels, and
at least one of a height and a thickness of the planarization layer in the first subpixel of the bend area is respectively different from at least one of a height and a thickness of the planarization layer in the second subpixel of the main area.

15. The display device according to claim 14, wherein the height of the planarization layer in the first subpixel of the bend area where light is emitted is greater than the height of the planarization layer in the second subpixel of the main area where light is emitted.

16. The display device according to claim 14, wherein the thickness of the planarization layer in the first subpixel of the bend area where light is emitted is less than the thickness of the planarization layer in the second subpixel of the main area where light is emitted.

17. The display device according to claim 14, wherein the planarization layer includes:
a first concave portion and a first slope portion extending from the first concave portion, both disposed in the first subpixel, and
a second concave portion and a second slope portion extending from the second concave, both disposed in the second subpixel, and
wherein an angle between the first slope portion and the first concave portion in the bend area is set to equal to an angle obtained by subtracting a first angle between the first concave portion and the second concave portion from a second angle between the second slope portion and the second concave portion.

18. The display device according to claim 14, further comprising:
a first electrode in the first subpixel and disposed on the planarization layer; and
a second electrode in the second subpixel and disposed on the planarization layer,
wherein the first electrode surrounds only a part of an emitting layer of the first subpixel, and the second electrode surrounds entirely an emitting layer of the second subpixel.

19. The display device according to claim 14, further comprising an encapsulation layer in the first subpixel of the bend area,
wherein the encapsulation layer includes a first layer and a second layer disposed on the first layer, and a refractive index of the first layer is higher than a refractive index of the second layer.

20. The display device according to claim 14, wherein each of the plurality of subpixels in the bend area includes a first electrode disposed on the planarization layer, and
heights of the first electrodes in the bend area increase as the subpixels get closer to a peripheral end of the bend area.
